(19) United States
(12) Patent Application Publication
(10) Pub. No.: US 2026/0144118 A1
(43) Pub. Date: May 21, 2026

(54) CERAMIC SUBSTRATE AND METHOD FOR MANUFACTURING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/875,627

(22) PCT Filed: Jun. 14, 2023
(86) PCT No.: PCT/KR2023/008165

§ 371 Date: Dec. 16, 2024

(30) Foreign Application Priority Data
Jun. 17, 2022 (KR) 10-2022-0073952

(51) Int. Cl. H10W 70/692; H10W 70/05

(52) U.S. Cl. CPC H10W 70/692; H10W 70/05

(57) ABSTRACT

Disclosed are a ceramic substrate and a method for manufacturing same. The ceramic substrate may include a ceramic material, a first electrode pattern and a second electrode pattern formed on upper and lower surfaces of the ceramic material, and a third electrode pattern formed on the upper surface of the ceramic material while being spaced apart from the first electrode pattern. The first electrode pattern is provided on an outer surface thereof with a silver-plating layer.

### TECHNICAL FIELD

Embodiments of the present disclosure relate to a ceramic substrate and a method for manufacturing same, and more particularly, to a ceramic substrate that can be miniaturized by implementing a driving circuit on a ceramic substrate for a power module, and a method for manufacturing same.

### BACKGROUND ART

Power semiconductor chips are responsible for basic parts of electronic systems as rectifiers and switches, and include diodes, transistors, thyristors, etc. With the development of a drive IC technology, an IC integrated circuit has been developed, and such an IC integrated circuit may process high-voltage and high-current signals compared to voltage and current of general digital or analog ICs.

In a case of a power module, implementing high efficiency, miniaturization, and heat dissipation performance of high-voltage and high-current semiconductor chips depending on use environments has been emerged as competitiveness. In general, since power inverters or motor drive circuit devices for electric vehicles, home appliances, multi-function peripherals, refrigerators, washing machines, etc., are used separately from different circuits due to characteristics of elements, there is a problem in that many functions are difficult to be implemented due to limitations in volume and size of a module and miniaturization is difficult.

The contents described in the Background Art are to help the understanding of the background of the disclosure, and may include contents that are not a disclosed conventional technology.

### DISCLOSURE

### Technical Problem

An object of the present disclosure is to provide a ceramic substrate that is highly efficient and can be miniaturized by applying a semiconductor device part for a power module and a drive circuit or general control drive IC part to one substrate and can improve electrical characteristics and reliability by preventing oxidation of an electrode pattern and a method for manufacturing same.

### Technical Solution

A ceramic substrate according to an embodiment of the present disclosure may include: a ceramic material; a first electrode pattern and a second electrode pattern formed on upper and lower surfaces of the ceramic material; and a third electrode pattern formed on the upper surface of the ceramic material while being spaced apart from the first electrode pattern. The first electrode pattern may be provided on an outer surface thereof with a silver-plating layer. The silver-plating layer may be formed to have a thickness of 1 μm or more.

A stepped surface in which a part of the upper surface of the ceramic material is recessed downward may be formed, and the first electrode pattern is formed on the stepped surface.

The ceramic material may include: a plurality of via holes formed to penetrate the upper and lower surfaces; and a metal filler filled in the via holes, wherein the second electrode pattern and the third electrode pattern may be formed to be in contact with exposed upper and lower surfaces of the metal filler.

A depth at which a part of the upper surface of the ceramic substrate is recessed downward may be equal to a thickness of the first electrode pattern. A thickness of the first electrode pattern may be larger than a thickness of the third electrode pattern.

The first electrode pattern may be configured to mount a power semiconductor chip, and the third electrode pattern may be configured to mount a drive IC chip.

The second electrode pattern may be formed throughout the lower surface of the ceramic material to face the first electrode pattern and the third electrode pattern.

The upper surface of the ceramic material may be divided into a first region and a second region on both sides based on a virtual dividing line, and the first region may be formed with the stepped surface, the first electrode pattern being disposed in the first region, the third electrode pattern being disposed in the second region. The first region may be located at a lower position than the second region, and an area of the first region may be larger than an area of the second region.

A method for manufacturing a ceramic substrate according to an embodiment of the present disclosure may include: preparing a ceramic material; forming a first electrode pattern and a second electrode pattern on upper and lower surfaces of the ceramic material; and forming a third electrode pattern on the upper surface of the ceramic material while being spaced apart from the first electrode pattern, wherein the forming of the first electrode pattern and the second electrode pattern may include forming a silver-plating layer on an outer surface of the first electrode pattern.

In the forming of the silver-plating layer, the silver-plating layer may be formed to have a thickness of 1 μm or more.

The preparing of the ceramic material may include forming a stepped surface in which a part of the upper surface of the ceramic material is recessed downward is formed, and the first electrode pattern may be formed on the stepped surface.

The preparing of the ceramic material may further include: forming a plurality of via holes penetrating the upper and lower surfaces of the ceramic material; filling a metal filler in the via holes; and sintering the metal filler.

The second electrode pattern and the third electrode pattern may be formed to be in contact with exposed upper and lower surfaces of the metal filler.

In the forming of the stepped surface, a depth at which a part of the upper surface of the ceramic substrate is recessed downward may be equal to a thickness of the first electrode pattern.

In the forming of the third electrode pattern, the third electrode pattern may be formed by screen printing a conductive paste. In the forming of the third electrode pattern, the third electrode pattern may be formed by a thin film process.

The forming of the third electrode pattern may further include sintering.

### Advantageous Effects

The present disclosure can achieve high efficiency, miniaturization, and lightness by allowing a semiconductor device part for a power module and a drive circuit or general control drive IC part to operate on a single substrate.

In addition, the present disclosure can prevent a first electrode pattern from being oxidized when a sintering process is performed in order to strengthen a bonding strength of a third electrode pattern by forming a silver-plating layer with a thickness of 1 μm or more on an outer surface of the first electrode pattern on which a power semiconductor chip is mounted.

In addition, the present disclosure can increase current transfer efficiency and miniaturize a power module by connecting a second electrode pattern and a third electrode pattern by using a filling material filled in a via hole when voltage, current, and signal connection between the second electrode pattern formed on a lower surface of a ceramic material and the third electrode pattern, on which a drive IC chip is mounted, are required.

In addition, in the present disclosure, since a first electrode pattern is formed on a stepped surface in which a part of an upper surface of a ceramic material is recessed downward, even though the first electrode pattern is formed to be thicker than a third electrode pattern, a height difference with a third electrode pattern can be reduced to reduce a position adjustment time of a capillary during wire bonding to about ⅓.

In addition, the present disclosure can be utilized in various fields from electronic components to energy fields because it has a dual in line (DIL) structure of a hybrid structure in which a substrate for a power module and a drive IC are integrated.

In addition, in the present disclosure, a third electrode pattern thinner than a first electrode pattern and formed as a fine pattern is formed by screen printing, so that patterns can be precisely printed while automatically correcting a pattern position during printing.

### DESCRIPTION OF DRAWINGS

FIG. 1 is a perspective view illustrating a ceramic substrate according to an embodiment of the present disclosure.

FIG. 2 is an exploded perspective view illustrating the ceramic substrate according to an embodiment of the present disclosure.

FIG. 3 is a plan view illustrating the ceramic substrate according to an embodiment of the present disclosure.

FIG. 4 is a cross-sectional view taken along line a-a′ in FIG. 3.

FIG. 5 is a photograph illustrating surfaces before and after sintering of ceramic substrates manufactured according to an embodiment of the present disclosure and comparative examples 1 to 3.

FIG. 6 is an enlarged plan view of a region A in FIG. 3.

FIG. 7 is a partial perspective view illustrating a state in which a drive IC chip is mounted on the ceramic substrate according to an embodiment of the present disclosure and wires are connected.

FIG. 8 is a side view illustrating a state in which a power semiconductor chip and a drive IC chip are mounted on the ceramic substrate according to an embodiment of the present disclosure and wires are connected.

FIG. 9 is a flow chart for explaining a method for manufacturing the ceramic substrate according to an embodiment of the present disclosure.

FIG. 10 is a cross-sectional view for explaining the method for manufacturing the ceramic substrate according to an embodiment of the present disclosure.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

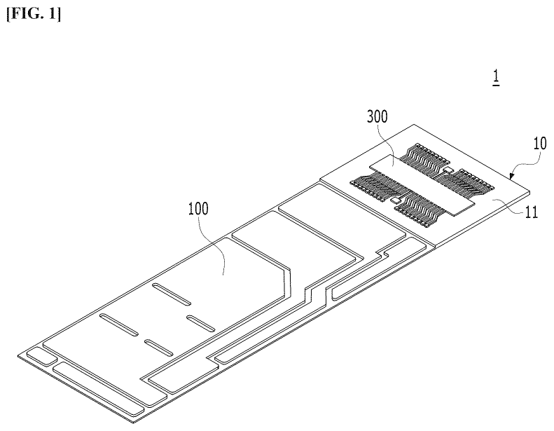

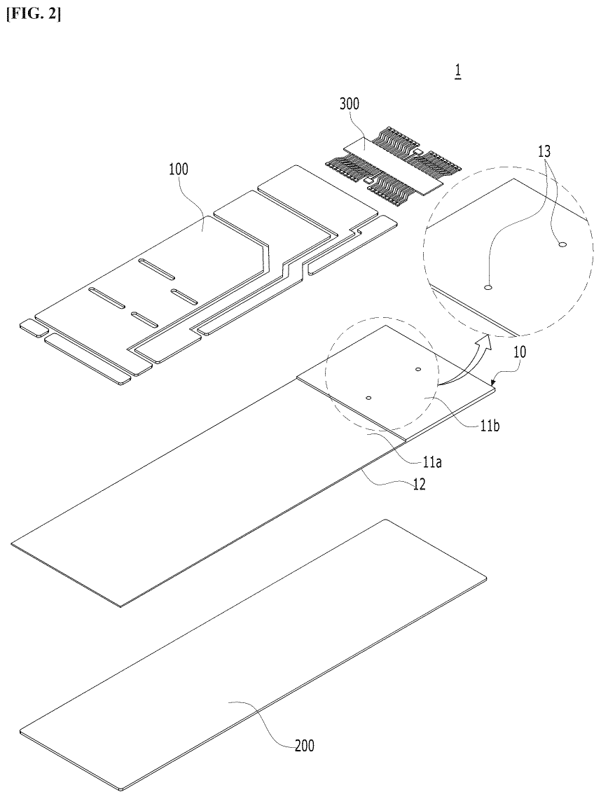

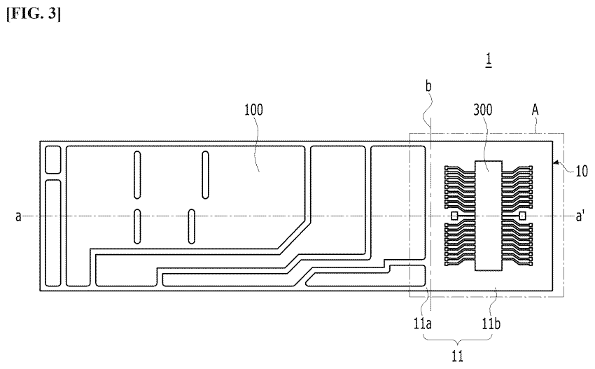

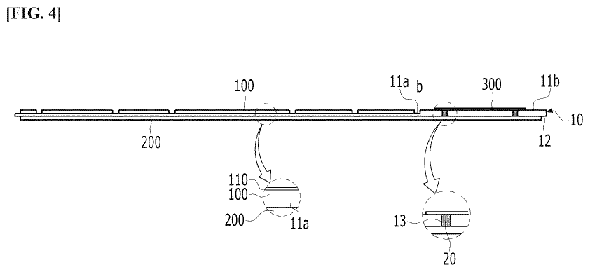

FIG. 1 is a perspective view illustrating a ceramic substrate according to an embodiment of the present disclosure, FIG. 2 is an exploded perspective view illustrating the ceramic substrate according to an embodiment of the present disclosure, FIG. 3 is a plan view illustrating the ceramic substrate according to an embodiment of the present disclosure, and FIG. 4 is a cross-sectional view taken along line a-a′ in FIG. 3.

Referring to FIGS. 1 to 3, a ceramic substrate 1 according to an embodiment of the present disclosure may include a ceramic material 10, a first electrode pattern 100, a second electrode pattern 200, and a third electrode pattern 300.

The ceramic material 10 may be, for example, one of alumina (Al₂O₃), AlN, SiN, and Si₃N₄. The thickness of the ceramic material 10 is 0.3 mm to 0.4 mm. For example, the thickness of the ceramic material 10 may be prepared to be 0.32 mm or 0.38 mm.

Referring to FIG. 4, the ceramic material 10 may include a plurality of via holes 13 formed to penetrate upper and lower surfaces 11 and 12 thereof. The via holes 13 may be filled with a metal filler 20. The metal filler 20 may be any one of Ag, W, Mo, and an Ag alloy, but is not limited thereto. The metal filler 20 filled in the via hole 13 may be fixed to the via hole 13 through a sintering process, and may conduct electricity between the second electrode pattern 200 and the third electrode pattern 300 facing each other with the via hole 13 interposed therebetween.

In the present embodiment, the total number of via holes 13 is 2, but is not limited thereto. Preferably, the via hole 13 is formed to have a diameter of 0.1 mm or more and 0.3 mm or less. When the via hole 13 is formed to have a diameter of 0.1 mm or more and 0.3 mm or less, the metal filler 20 may be filled in the via hole 13 without voids. The diameter of the via hole 13 may be formed corresponding to the thickness of the ceramic material 10. For example, when the thickness of the ceramic material 10 is 0.38 mm, the diameter of the via hole 13 is preferably 0.1 mm or more and 0.2 mm or less corresponding to the thickness. When the diameter of the via hole 13 exceeds 0.2 mm, it may be problematic that the filling efficiency decreases and the metal filler 20 may fall out of the via hole 13 after sintering.

The first electrode pattern 100 and the second electrode pattern 200 may be formed on the upper and lower surfaces 11 and 12 of the ceramic material 10. In addition, the third electrode pattern 300 may be formed on the upper surface 11 of the ceramic material 10 while being spaced apart from the first electrode pattern 100. Specifically, the upper surface of the ceramic material 10 may be divided into a first region 11a and a second region 11b on both sides based on a virtual dividing line b (see FIGS. 3 and 4). The first region 11a may be formed with a stepped surface in a downwardly recessed shape, may be located at a lower position than the second region 11b, and may be formed to have a larger area than the second region 11b. The first region 11a may have the first electrode pattern 100 disposed therein, and the second region 11b may have the third electrode pattern 300 disposed therein.

The first electrode pattern 100 and the second electrode pattern 200 may be provided as metal foils and brazed to the upper surface 11 and the lower surface 12 of the ceramic material 10, and then may be formed as electrode patterns by etching, machining, etc. The brazing may utilize a brazing layer made of an alloy material including at least one of Ag, AgCu, and AgCuTi. Heat treatment for the brazing may be performed at 780° C. to 900° C. Such a ceramic substrate 1 is referred to as an active metal brazing (AMB) substrate, and such an AMB substrate has excellent durability and heat dissipation performance. The embodiment describes an AMB substrate as an example, but a direct bonding copper (DBC) substrate or a thick printing copper (TPC) substrate may also be applied.

The present embodiment describes an example in which the second electrode pattern 200 is formed in a flat shape; the present disclosure is not limited thereto and the second electrode pattern 200 may be formed in a circuit pattern shape depending on a semiconductor chip, product specifications, etc. The first electrode pattern 100 and the second electrode pattern 200 may each be made of one of Cu, a Cu alloy (CuMo, etc.), and Al, and may be preferably made of Cu and a Cu alloy.

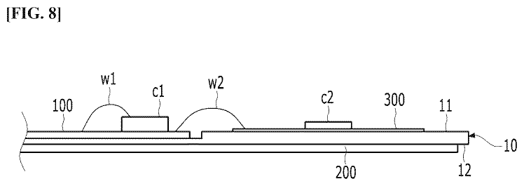

The first electrode pattern 100 may be configured to mount a power semiconductor chip c1 (see FIG. 8). For example, the first electrode pattern 100 may be mounted with a SiC and GaN-based power semiconductor chip c1 that can satisfy requirements such as high voltage, high current, high temperature operation, use in a high-frequency environment, high-speed switching, power loss minimization, and small chip size. In addition to the SiC chip and the GaN chip, the first electrode pattern 100 may be mounted with various elements such as a Si chip, a metal oxide semiconductor field effect transistor (MOSFET), an insulated gate bipolar transistor (IGBT), a junction field effect transistor (JFET), a high electric mobility transistor (HEMT), and a diode. Such a first electrode pattern 100 may have a plurality of electrodes disposed in a predetermined pattern.

The third electrode pattern 300 may be configured to mount a drive IC chip c2 (see FIG. 8). For example, the third electrode pattern 300 may mount a silicon on insulator (SOI)-based driving, electrical, and electronic control element. The third electrode pattern 300 may be made of one of Ag, Au, Pt, Cu, an Ag alloy, and carbon black, for example.

Since the first electrode pattern 100 is configured to mount the power semiconductor chip c1 and is a portion where a large current flows, and the third electrode pattern 300 is configured to mount the drive IC chip c2 and is a portion where a small current flows, the thickness of the first electrode pattern 100 may be larger than the thickness of the third electrode pattern 300. For example, the thickness of the first electrode pattern 100 may be about 0.3 mm, and the thickness of the third electrode pattern 300 may be about 20 μm; however, the present disclosure is not limited thereto.

The third electrode pattern 300 may be formed by screen printing a conductive paste. Since the third electrode pattern 300 is formed as a fine pattern having a line and space shape of 100 μm to 150 μm, the third electrode pattern 300 may be precisely formed when the method of screen printing a conductive paste is applied. Since the standard of the line and space is a thickness, the line and space shape of the third electrode pattern 300 thinner than the first electrode pattern 100 is finer than that of the first electrode pattern 100. The screen printing method can precisely implement such a fine pattern. Since the screen printing is suitable for forming a fine pattern because it has a high curing speed and excellent adhesiveness and flexibility. In addition, when a table on which a product is seated is disposed below a screen mask and a screen process is performed, a program performs printing while automatically correcting the position of the table through a reference index hole on the side, so that a pattern can be precisely printed at a correct position.

On the other hand, the third electrode pattern 300 may also be formed by a thin film process. The thin film process may form a pattern having a desired shape by using a pattern mask after a metal thin film is formed by a method such as deposition, coating, or application. The thin film process may be applied when a fine pattern with a line and space shape of 15 μm to 30 μm is formed to have a maximum thickness of 2 μm.

In this way, the third electrode pattern 300 formed on the upper surface 11 of the ceramic material 10 by the screen printing or the thin film process may be subjected to a sintering process in which heat of 350° C. to 600° C. is applied to strengthen a bonding strength. The sintering process may be performed in an oxidizing atmosphere, and the oxidizing atmosphere may mean an air atmosphere containing some oxygen or an atmosphere in which oxygen is mixed with an inert gas such as nitrogen or argon.

When the sintering process is performed on the third electrode pattern 300 at a temperature of 200° C. or higher in an oxidizing atmosphere, the first electrode pattern 100 made of Cu material is easily oxidized and turns black, and becomes an insulator. Since the first electrode pattern 100 is a part where the power semiconductor chip c1 is mounted, when oxidation occurs, there is a problem in that electrical characteristics deteriorate and reliability decreases. When additional heat treatment is performed under a reducing atmosphere including hydrogen in order to remove oxidation, the metal oxide is reduced to metal as oxygen is separated, but the process steps are complicated and properties may change. Accordingly, in the ceramic substrate 1 according to an embodiment of the present disclosure, a silver-plating layer 110 may be formed on an outer surface of the first electrode pattern 100 in order to prevent oxidation of the first electrode pattern 100. The silver-plating layer 110 may be made of Ag or an Ag alloy, and may effectively prevent oxidation of the first electrode pattern 100 due to the high oxidation resistance of Ag. The silver-plating layer 110 may be formed before the third electrode pattern 300 is formed by the screen printing or the thin film process. Such a silver-plating layer 110 may be formed to cover exposed outer surfaces of the first electrode pattern 100 formed in the first region 11a, that is, the upper surface and the outer surface. The silver-plating layer 110 may be formed by electroless plating that is simple in process and inexpensive; however, the present disclosure is not limited thereto.

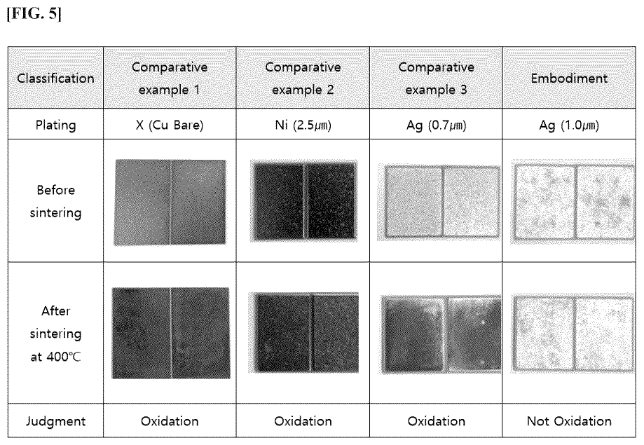

FIG. 5 is a photograph illustrating surfaces before and after sintering of ceramic substrates manufactured according to an embodiment of the present disclosure and comparative examples 1 to 3.

Preferably, the silver-plating layer 110 may be formed to have a thickness of 1 μm or more. Referring to FIG. 5, in the comparative example 1 in which no plating layer is formed on a Cu metal pattern, it can be confirmed that the Cu metal pattern is oxidized and turns black when a sintering process is performed at 400° C. in an oxidizing atmosphere. Also in the comparative example 2 in which a Ni plating layer with a thickness of 2.5 μm is formed on a Cu metal pattern, it can be confirmed that the Cu metal pattern is oxidized and turns black after a sintering process is performed at 400° C. Referring to the comparative example 3 and the embodiment, it can be confirmed that in the comparative example 3 in which an Ag plating layer with a thickness of 0.7 μm is formed on a Cu metal pattern, oxidation occurs when a sintering process is performed at 400° C. in an oxidizing atmosphere, but in the embodiment in which an Ag plating layer with a thickness of 1 μm is formed on a Cu metal pattern, it can be confirmed that no oxidation occurs. In this way, when the silver-plating layer 110 is formed on the outer surface of the Cu metal pattern to have a thickness of 1 μm or more, it can be confirmed that oxidation of the Cu metal pattern can be prevented.

The silver-plating layer 110 may effectively prevent oxidation of the first electrode pattern 100, on which the power semiconductor chip c1 is mounted, without affecting the quality required for the ceramic substrate, such as solderability or wire bondability. The solderability is a measurement of the wettability of soldering, and it was confirmed that a ceramic substrate in which a silver-plating layer of 1 μm or more is formed on a Cu electrode pattern has good solderability because it has an average measurement value of 95% or more. The wire bondability is a test of an adhesive strength between a bonding wire and a bonding portion. When a shear force is 700 g or more, the wire bondability is good. It was confirmed that the ceramic substrate in which a silver-plating layer of 1 μm or more is formed on the Cu electrode pattern has good bondability because it has an average measurement value of 1272 g or more.

The second electrode pattern 200 and the third electrode pattern 300 may be formed to be in contact with exposed upper and lower surfaces of the metal filler 20. The via hole 13 is formed in a region where the second electrode pattern 200 and the third electrode pattern 300 face each other. Accordingly, the second electrode pattern 200 and the third electrode pattern 300 may be in contact with the exposed upper and lower surfaces of the metal filler 20 filled in the via hole 13. Since the ceramic material 10 is made of an insulating material, the electrical connection between the electrode patterns formed on the upper surface 11 and the lower surface 12 is not possible. Accordingly, when voltage, current, and signal connection between the second electrode pattern 200 formed on the lower surface 12 of the ceramic material 10 and the third electrode pattern 300 on which the drive IC chip c2 is mounted are required, the second electrode pattern 200 and the third electrode pattern 300 can be connected using the metal filler 20 filled in the via hole 13 to increase the current transfer efficiency and enable miniaturization of a power module.

The second electrode pattern 200 may be formed over a large area across the entire lower surface 12 of the ceramic material 10 in order to facilitate heat transfer. Such a second electrode pattern 200 may have one side region facing the first electrode pattern 100 and the other side region facing the third electrode pattern 300.

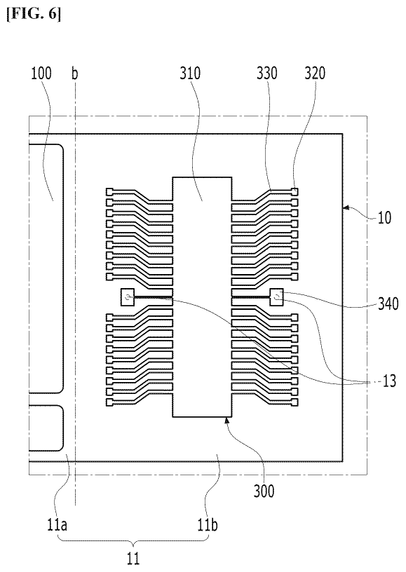

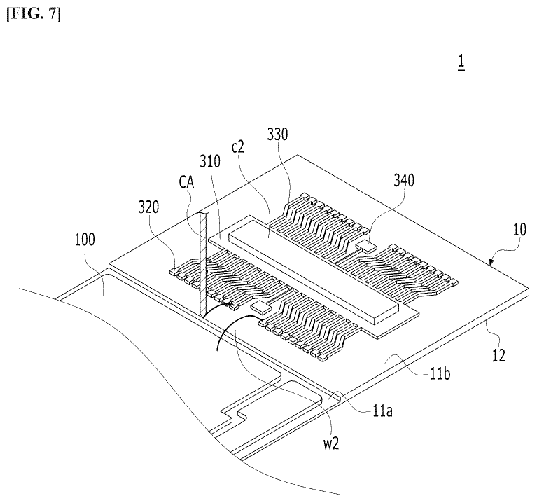

FIG. 6 is an enlarged plan view of a region A in FIG. 3, and FIG. 7 is a partial perspective view illustrating a state in which a drive IC chip is mounted on the ceramic substrate according to an embodiment of the present disclosure and wires are connected.

Referring to FIG. 6, the third electrode pattern 300 may include a first pattern region 310 configured to mount the drive IC chip c2, a second pattern region 320 to which one end of a second wire w2 is connected, a third pattern region 330 connecting the first pattern region 310 and the second pattern region 320, and a fourth pattern region 340 formed at a position corresponding to the via hole 13. A plurality of second pattern regions 320 may be disposed on both sides of the first pattern region 310, and the third pattern region 330 may be extended to both sides by a certain length to connect the first pattern region 310 and the second pattern region 320.

Referring to FIG. 7, in a state in which the drive IC chip c2 is mounted on the first pattern region 310 of the third electrode pattern 300, the second pattern region 320 of the third electrode pattern 300 and the first electrode pattern 100 may be connected with the second wire w2 by using a capillary CA. The second wire w2 may be made of Au, but is not limited thereto.

The capillary CA performing the wire bonding process may form a primarily bonding portion on the upper part of the second pattern region 320 of the third electrode pattern 300, move upward in the vertical direction, and then move to the first electrode pattern 100 to form a secondarily bonding portion. In such a case, since the thickness of the third electrode pattern 300 is about 20 μm and the thickness of the first electrode pattern 100 is about 0.3 mm, there is a height difference of about 280 μm. Accordingly, since time is required to adjust upper and lower positions of the capillary CA aligned with the thickness of the third electrode pattern 300 so as to match the thickness of the first electrode pattern 100, the manufacturing time may be increased and productivity may be decreased.

In order to solve such problems, the ceramic substrate 1 of the present disclosure can reduce a height difference between the first electrode pattern 100 and the third electrode pattern 300 by forming a part of the upper surface 11 of the ceramic material 10 in a stepped manner. Specifically, when the upper surface 11 of the ceramic material 10 is divided into the first region 11a and the second region 11b based on the virtual dividing line b (see FIGS. 3 and 4), the first region 11a may be formed with a stepped surface in a downwardly recessed shape. The first electrode pattern 100 may be formed on the stepped surface of the first region 11a recessed downwardly. Accordingly, even though the first electrode pattern 100 is formed thicker than the third electrode pattern 300, a height difference with the third electrode pattern 300 formed in the second region 11b that is not recessed may be reduced. In such a case, a depth at which a part of the upper surface 11 of the ceramic material 10 is recessed downward may be equal to the thickness of the first electrode pattern 100. In this way, by reducing the height difference between the first electrode pattern 100 and the third electrode pattern 300, the position adjustment time of the capillary may be reduced by about ⅓.

FIG. 8 is a side view illustrating a state in which a power semiconductor chip and a drive IC chip are mounted on the ceramic substrate according to an embodiment of the present disclosure and wires are connected.

Referring to FIG. 8, the power semiconductor chip c1 may bonded to the first electrode pattern 100 and may be connected to the first electrode pattern 100 by a first wire w1. The first wire w1 may be an Al wire, but is not limited thereto. In addition, the drive IC chip c2 may be bonded to the first pattern region 310 of the third electrode pattern 300, and the second pattern region 320 of the third electrode pattern 300 may be connected to the first electrode pattern 100 by the second wire w2. In this way, the ceramic substrate 1 according to an embodiment of the present disclosure is characterized by being the ceramic substrate 1 having a dual electrode structure in which two functional chips, namely, the power semiconductor chip c1 and the drive IC chip c2, are mounted on the upper surface 11 of the ceramic material 10. The ceramic substrate 1 having such a dual electrode structure has the advantages of being able to reduce the size, reduce the weight, increase the heat dissipation efficiency, and be applied to home appliances and electric vehicle modules in various ways, compared to cases where a drive IC module and a power module are provided separately.

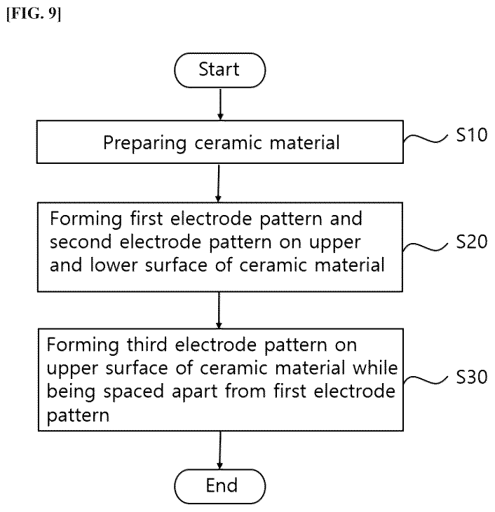

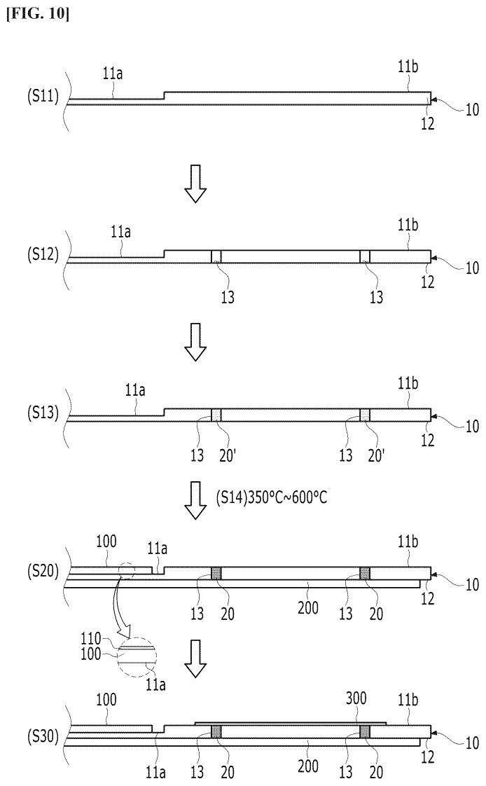

FIG. 9 is a flow chart for explaining a method for manufacturing the ceramic substrate according to an embodiment of the present disclosure, and FIG. 10 is a cross-sectional view for explaining the method for manufacturing the ceramic substrate according to an embodiment of the present disclosure.

Referring to FIG. 9, the method for manufacturing the ceramic substrate according to an embodiment of the present disclosure may include step S10 of preparing the ceramic material 10, step S20 of forming the first electrode pattern 100 and the second electrode pattern 200 on the upper and lower surfaces 11 and 12 of the ceramic material 10, and step S30 of forming the third electrode pattern 300 on the upper surface of the ceramic material 10 while being spaced apart from the first electrode pattern 100.

In step S10 of preparing the ceramic material 10, the ceramic material 10 is prepared as any one of alumina (Al₂O₃), AlN, SiN, and Si₃N₄. The thickness of the ceramic material 10 is 0.3 mm to 0.4 mm. For example, the ceramic material 10 may be prepared to have a thickness of 0.32 mm or 0.38 mm.

Referring to FIGS. 9 and 10, step S10 of preparing a ceramic material 10 may include step S11 of forming a stepped surface in which a part of the upper surface 11 of the ceramic material 10 is recessed downward, step S12 of forming the plurality of via holes 13 penetrating the upper and lower surfaces 11 and 12 of the ceramic material 10, step S13 of filling the via holes 13 with the metal filler 20, and step S14 of sintering the metal filler 20. In step S11 of forming the stepped surface, the depth at a part of the upper surface 11 of the ceramic material 10 recessed downward may be equal to the thickness of the first electrode pattern 100.

In step S12 of forming the plurality of via holes 13 penetrating the upper and lower surfaces 11 and 12 of the ceramic material 10, the plurality of via holes 13 penetrating the upper and lower surfaces 11 and 12 of the ceramic material 10 may be formed using a laser drilling method or a photo via method. The via holes 13 may be formed in a region where the second electrode pattern 200 and the third electrode pattern 300 face each other so as to connect the second electrode pattern 200 and the third electrode pattern 300. In the present embodiment, the total number of via holes 13 is 2, but is not limited thereto.

Preferably, the via hole 13 is formed to have a diameter of 0.1 mm or more and 0.3 mm or less. When the via hole 13 is formed to have a diameter of 0.1 mm or more and 0.3 mm or less, the metal filler 20 may be filled in the via hole 13 without voids. The diameter of the via hole 13 may correspond to the thickness of the ceramic material 10. For example, when the thickness of the ceramic material 10 is 0.38 mm, the via hole 13 is preferably formed to have a diameter of 0.1 mm or more and 0.2 mm or less in correspondence to the thickness. When the diameter of the via hole 13 exceeds 0.2 mm, it may be problematic that the filling efficiency decreases and the metal filler 20 may fall out of the via hole 13 after sintering.

In step S13 of filling the via hole 13 with the metal filler 20, the metal filler 20 may be filled in the via hole 13 in the form of metal ink (paste). Such a metal filler 20 may be any one of Ag, W, Mo, and an Ag alloy, but is not limited thereto.

In step S14 of sintering, the metal filler 20 filled in the via hole 13 may be fixed to the via hole 13 through a drying and sintering (sintering) process. The step S14 of sintering may be performed at a temperature range of 350° C. to 600° C., but may be performed at various temperatures depending on the metal filler 20.

Subsequently, in step S20 of forming the first electrode pattern 100 and the second electrode pattern 200 on the upper and lower surfaces 11 and 12 of the ceramic material 10, the first electrode pattern 100 may be formed in the first region 11a of the upper surface 11 of the ceramic material 10 and the second electrode pattern 200 may be formed on the lower surface 12 of the ceramic material 10. The first electrode pattern 100 may be formed on the stepped surface of the first region 11a recessed downwardly. Accordingly, even though the first electrode pattern 100 is formed thicker than the third electrode pattern 300, a height difference with the third electrode pattern 300 formed in the second region 11b that is not recessed may be reduced. In such a case, a depth at which a part of the upper surface 11 of the ceramic material 10 is recessed downward may be equal to the thickness of the first electrode pattern 100. In this way, by reducing the height difference between the first electrode pattern 100 and the third electrode pattern 300, the position adjustment time of the capillary performing the wire bonding process may be reduced by about ⅓ and productivity may be improved.

In step S20 of forming the first electrode pattern 100 and the second electrode pattern 200, the first electrode pattern 100 and the second electrode pattern 200 may be provided as metal foils and brazed to the upper surface 11 and the lower surface 12 of the ceramic material 10. The brazing may utilize a brazing layer made of an alloy material including at least one of Ag, AgCu, and AgCuTi. Heat treatment for the brazing may be performed at 780° C. to 900° C. The first electrode pattern 100 and the second electrode pattern 200 may each be made of one of Cu, a Cu alloy (CuMo, etc.), and Al, for example.

On the other hand, the metal filler 20 may be filled into the via hole 13 of the ceramic material 10 and dried, and then a metal layer provided as a metal foil on the upper surface 11 and the lower surface 12 of the ceramic material 10 may be brazed. The drying process may temporarily fix the state in which the metal filler 20 is filled into the via hole 13, and during the brazing process, the metal filler 20 may be sintered to conduct electricity between the second electrode pattern 200 and the third electrode pattern 300.

Subsequently, in step S30 of forming the third electrode pattern 300 on the upper surface of the ceramic material 10 while being spaced apart from the first electrode pattern 100, the third electrode pattern 300 may be formed by screen printing a conductive paste. Since the third electrode pattern 300 is formed as a fine pattern having a line and space shape of 100 μm to 150 μm, the third electrode pattern 300 is preferably formed by screen printing a conductive paste. Since the standard of the line and space is a thickness, the line and space shape of the third electrode pattern 300 thinner than the first electrode pattern 100 is finer than that of the first electrode pattern 100. In order to precisely implement such a fine pattern, screen printing is preferable. Since the screen printing is suitable for forming a fine pattern because it has a high curing speed and excellent adhesiveness and flexibility. In addition, when a table on which a product is seated is disposed below a screen mask and a screen process is performed, a program performs printing while automatically correcting the position of the table through a reference index hole on the side, so that a pattern can be precisely printed at a correct position.

On the other hand, in step S30 of forming the third electrode pattern 300 on the upper surface of the ceramic material 10 while being spaced apart from the first electrode pattern 100, the third electrode pattern 300 may also be formed by a thin film process. The thin film process may form a pattern having a desired shape by using a pattern mask after a metal thin film is formed by a method such as deposition, coating, or application. The thin film process may be applied when a fine pattern with a line and space shape of 15 μm to 30 μm is formed to have a maximum thickness of 2 μm.

On the other hand, step S30 of forming the third electrode pattern 300 may further include a step of sintering. In the step of sintering, a sintering process may be performed at 350° C. to 600° C. to strengthen the bonding strength of the third electrode pattern 300 formed on the upper surface 11 of the ceramic material 10 by screen printing or a thin film process. In such a case, the sintering process may be performed in an oxidizing atmosphere, and the oxidizing atmosphere may mean an air atmosphere containing some oxygen or an atmosphere in which oxygen is mixed with an inert gas such as nitrogen or argon.

When sintering process is performed on the third electrode pattern 300 at a temperature of 200° C. or higher in an oxidizing atmosphere, the first electrode pattern 100 made of Cu material is easily oxidized and turns black, and becomes an insulator. Since the first electrode pattern 100 is a part where the power semiconductor chip c1 is mounted, when oxidation occurs, there is a problem in that electrical characteristics deteriorate and reliability decreases. When additional heat treatment is performed under a reducing atmosphere including hydrogen in order to remove oxidation, the metal oxide is reduced to metal as oxygen is separated, but the process steps are complicated and properties may change.

Accordingly, the method for manufacturing the ceramic substrate according to an embodiment of the present disclosure may include a step of forming the silver-plating layer 110 on the outer surface of the first electrode pattern 100 before step S30 of forming the third electrode pattern 300. That is, step S20 of forming the first electrode pattern 100 and the second electrode pattern 200 may include the step of forming the silver-plating layer 110 on the outer surface of the first electrode pattern 100. The silver-plating layer 110 may be formed by electroless plating that is simple in process and inexpensive, and may be formed to cover exposed outer surfaces of the first electrode pattern 100, that is, the upper surface and the outer surface. The silver-plating layer 110 may be made of Ag or an Ag alloy, and may effectively prevent oxidation of the first electrode pattern 100 due to the high oxidation resistance of Ag. Preferably, the silver-plating layer 110 is formed to have a thickness of 1 μm or more. The silver-plating layer 110 formed to have a thickness of 1 μm or more may effectively prevent oxidation of the first electrode pattern 100, on which the power semiconductor chip c1 is mounted, without affecting the quality required for the ceramic substrate, such as solderability or wire bondability.

The second electrode pattern 200 and the third electrode pattern 300 may be formed to be in contact with exposed upper and lower surfaces of the metal filler 20. The via hole 13 is formed in a region where the second electrode pattern 200 and the third electrode pattern 300 face each other. Accordingly, the second electrode pattern 200 and the third electrode pattern 300 may be in contact with the exposed upper and lower surfaces of the metal filler 20 filled in the via hole 13. Since the ceramic material 10 is made of an insulating material, the electrical connection between the electrode patterns formed on the upper surface 11 and the lower surface 12 is not possible. Accordingly, when voltage, current, and signal connection between the second electrode pattern 200 formed on the lower surface 12 of the ceramic material 10 and the third electrode pattern 300 on which the drive IC chip c2 is mounted are required, the second electrode pattern 200 and the third electrode pattern 300 can be connected using the metal filler 20 filled in the via hole 13 to increase the current transfer efficiency and enable miniaturization of a power module.

The above description is merely intended to illustratively describe the technical spirit of the present disclosure, and various changes and modifications can be made by those skilled in the art to which the present disclosure pertains without departing from the essential features of the present disclosure. Therefore, the embodiments disclosed in the present disclosure are not intended to limit the technical spirit of the present disclosure, but are intended to describe the present disclosure. The scope of the technical spirit of the present disclosure is not limited by these embodiments. The scope of the present disclosure should be interpreted by the accompanying claims and all technical spirits falling within the equivalent scope thereto should be interpreted as being included in the scope of the present disclosure.

1. A ceramic substrate comprising:
a ceramic material;
a first electrode pattern and a second electrode pattern formed on upper and lower surfaces of the ceramic material; and
a third electrode pattern formed on the upper surface of the ceramic material while being spaced apart from the first electrode pattern,
wherein the first electrode pattern is provided on an outer surface thereof with a silver-plating layer.

2. The ceramic substrate of claim 1, wherein the silver-plating layer is formed to have a thickness of 1 μm or more.

3. The ceramic substrate of claim 1, wherein a stepped surface in which a part of the upper surface of the ceramic material is recessed downward is formed, and
the first electrode pattern is formed on the stepped surface.

4. The ceramic substrate of claim 1, wherein the ceramic material comprises:
a plurality of via holes formed to penetrate the upper and lower surfaces; and
a metal filler filled in the via holes,
wherein the second electrode pattern and the third electrode pattern are formed to be in contact with exposed upper and lower surfaces of the metal filler.

5. The ceramic substrate of claim 3, wherein a depth at which a part of the upper surface of the ceramic substrate is recessed downward is equal to a thickness of the first electrode pattern.

6. The ceramic substrate of claim 1, wherein a thickness of the first electrode pattern is larger than a thickness of the third electrode pattern.

7. The ceramic substrate of claim 1, wherein the first electrode pattern is configured to mount a power semiconductor chip, and
the third electrode pattern is configured to mount a drive IC chip.

8. The ceramic substrate of claim 1, wherein the second electrode pattern is formed throughout the lower surface of the ceramic material to face the first electrode pattern and the third electrode pattern.

9. The ceramic substrate of claim 3, wherein the upper surface of the ceramic material is divided into a first region and a second region on both sides based on a virtual dividing line, and
the first region is formed with the stepped surface, the first electrode pattern being disposed in the first region, the third electrode pattern being disposed in the second region.

10. The ceramic substrate of claim 9, wherein the first region is located at a lower position than the second region.

11. The ceramic substrate of claim 9, wherein an area of the first region is larger than an area of the second region.

12. A method for manufacturing a ceramic substrate, comprising:
preparing a ceramic material;
forming a first electrode pattern and a second electrode pattern on upper and lower surfaces of the ceramic material; and
forming a third electrode pattern on the upper surface of the ceramic material while being spaced apart from the first electrode pattern,
wherein the forming of the first electrode pattern and the second electrode pattern comprises forming a silver-plating layer on an outer surface of the first electrode pattern.

13. The method for manufacturing a ceramic substrate of claim 12, wherein in the forming of the silver-plating layer, the silver-plating layer is formed to have a thickness of 1 μm or more.

14. The method for manufacturing a ceramic substrate of claim 12, wherein the preparing of the ceramic material comprises forming a stepped surface in which a part of the upper surface of the ceramic material is recessed downward is formed, and the first electrode pattern is formed on the stepped surface.

15. The method for manufacturing a ceramic substrate of claim 12, wherein the preparing of the ceramic material further comprises:
forming a plurality of via holes penetrating the upper and lower surfaces of the ceramic material;
filling a metal filler in the via holes; and
sintering the metal filler.

16. The method for manufacturing a ceramic substrate of claim 15, wherein the second electrode pattern and the third electrode pattern are formed to be in contact with exposed upper and lower surfaces of the metal filler.

17. The method for manufacturing a ceramic substrate of claim 14, wherein in the forming of the stepped surface, a depth at which a part of the upper surface of the ceramic substrate is recessed downward is equal to a thickness of the first electrode pattern.

18. The method for manufacturing a ceramic substrate of claim 12, wherein in the forming of the third electrode pattern, the third electrode pattern is formed by screen printing a conductive paste.

19. The method for manufacturing a ceramic substrate of claim 12, wherein in the forming of the third electrode pattern, the third electrode pattern is formed by a thin film process.

20. The method for manufacturing a ceramic substrate of claim 12, wherein the forming of the third electrode pattern further comprises sintering.
